(19) United States
(12) Patent Application Publication
(10) Pub. No.: US 2008/0130698 A1
(43) Pub. Date: Jun. 5, 2008

(54) NITRIDE-BASED SEMICONDUCTOR DEVICE AND METHOD OF FABRICATING THE SAME

(75) Inventors: Yasuyuki BESSHO, Uji-shi (JP); Yasuhiko Nomura, Osaka-shi (JP); Masayuki Hata, Kadoma-shi (JP)

Correspondence Address: DITTHAVONG MORI & STEINER, P.C., 918 Prince St., Alexandria, VA, 22314, US

(73) Assignee: SANYO ELECTRIC CO., LTD., Moriguchi-shi (JP)

(21) Appl. No.: 11/948,058

(22) Filed: Nov. 30, 2007

(30) Foreign Application Priority Data
Nov. 30, 2006 (JP) 2006-323582
Oct. 31, 2007 (JP) 2007-283225

(51) Int. Cl. H01S 5/026; H01L 33/00

(52) U.S. Cl. 372/45.01; 438/31; 257/E33.067

(57) ABSTRACT

A nitride-based semiconductor device includes a substrate constituted by nitride-based semiconductor, a nitride-based semiconductor layer formed on the substrate and constituted by nitride-based semiconductor, formed with a light waveguide extending in a first direction, and first step portions formed at least on regions other than the vicinity of facets of the light waveguide from a surface opposite to a side where the nitride-based semiconductor layer of the substrate is formed along the first direction in which the light waveguide extends.

### CROSS-REFERENCE TO RELATED APPLICATIONS

The priority application number JP2006-323582, Method of Fabricating a Nitride-Based Semiconductor Device, Nov. 30, 2006, Yasuyuki Bessho, JP2007-283225, Nitride-Based Semiconductor Device and Method of Fabricating the Same, Oct. 31, 2007, Yasuyuki Bessho, upon which this patent application is based is hereby incorporated by reference.

### BACKGROUND OF THE INVENTION

1. Field of the Invention

The present invention relates to a nitride-based semiconductor device and a method of fabricating the same, and more particularly, it relates to a nitride-based semiconductor device comprising a step of forming an element dividing groove and a method of fabricating the same.

2. Description of the Background Art

A method of fabricating a nitride-based semiconductor device comprising a step of forming an element dividing groove is known in general, as disclosed in Japanese Patent Laying-Open No. 2005-136093 for example.

The aforementioned Japanese Patent Laying-Open No. 2005-136093 discloses a method of fabricating a semiconductor device comprising steps of forming a semiconductor layer having a ridge portion (light waveguide) on a GaN substrate, forming a laser cavity bar by performing cleavage along a prescribed direction, forming an element separation groove (element dividing groove) in a laser cavity bar from a semiconductor layer side with a scriber (diamond needle) or the like, and forming an nitride-based semiconductor laser diode by dividing the laser cavity bar along the element separation groove.

In the conventional method of fabricating a semiconductor device proposed in Japanese Patent Laying-Open No. 2005-136093, however, the element separation groove (element dividing groove) is formed in the laser cavity bar from the semiconductor layer side with the scriber (diamond needle) or the like and hence breaks or cracks occur in the semiconductor layer resulting from contact of the scriber (diamond needle) and the semiconductor layer when forming the element separation groove and the ridge portion (light waveguide) is disadvantageously damaged. Consequently, the ridge portion may disadvantageously be damaged.

### SUMMARY OF THE INVENTION

A method of fabricating a nitride-based semiconductor device according to a first aspect of the present invention comprises steps of forming a nitride-based semiconductor layer having light waveguides extending in a first direction on a substrate, performing a first division along a second direction intersecting with the first direction in which the light waveguides extend, forming element dividing grooves extending in the first direction on regions spaced at prescribed distances from divided surfaces by the first division extending in the second direction on a surface opposite to a side on which the nitride-based semiconductor layer of the substrate is formed by irradiation of laser beam, and forming nitride-based semiconductor devices by performing a second division along the element dividing grooves.

A nitride-based semiconductor device according to a second aspect of the present invention comprises a substrate constituted by nitride-based semiconductor, a nitride-based semiconductor layer formed on the substrate and constituted by nitride-based semiconductor, formed with a light waveguide extending in a first direction, and first step portions formed at least on regions other than the vicinity of facets of the light waveguide from a surface opposite to a side where the nitride-based semiconductor layer of the substrate is formed along the first direction in which the light waveguide extends.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing an exemplary structure formed through a process of fabricating a GaN-based semiconductor laser chip according to a first embodiment of the present invention;

FIG. 2 is a sectional view showing a detailed structure of a semiconductor layer in the vicinity of a center of the GaN-based semiconductor laser chip shown in FIG. 1;

FIG. 3 is a perspective view showing another exemplary structure formed through the process of fabricating a GaN-based semiconductor laser chip according to the first embodiment of the present invention;

FIG. 4 is a perspective view showing a structure in which another exemplary GaN-based semiconductor laser chip according to the first embodiment shown in FIG. 3 is mounted on a radiator base;

FIG. 5 is a perspective view for illustrating the process of fabricating the GaN-based semiconductor laser chip according to the first embodiment shown in FIG. 1 in the wafer state (wafer process);

FIG. 6 is a plan view for illustrating the process of fabricating the GaN-based semiconductor laser chip according to the first embodiment shown in FIG. 1 in the wafer state (wafer process);

FIGS. 7 to 10 are perspective views for illustrating a process of fabricating the GaN-based semiconductor laser chip according to the first embodiment shown in FIG. 1 subsequent to the wafer process (process of fabricating chips);

FIG. 11 is a perspective view showing a structure in which a GaN-based semiconductor laser chip according to a first modification of the first embodiment of the present invention is mounted on a radiator base;

FIGS. 12 and 13 are perspective views showing a structure of a GaN-based semiconductor laser chip according to a second embodiment of the present invention;

FIG. 14 is a perspective view for illustrating a process of fabricating the GaN-based semiconductor laser chip according to the second embodiment shown in FIGS. 12 and 13;

FIG. 15 is a perspective view showing a structure of a GaN-based semiconductor laser chip according to a third embodiment of the present invention;

FIG. 16 is a perspective view showing a structure in which a GaN-based semiconductor laser chip according to the third embodiment shown in FIG. 15 is mounted on a radiator base;

FIG. 17 is a perspective view for illustrating a process of fabricating the GaN-based semiconductor laser chip according to the third embodiment shown in FIGS. 15 and 16;

FIG. 18 is a perspective view showing a structure in which a GaN-based semiconductor laser chip according to a modification of the third embodiment of the present invention is mounted on a radiator base;

FIG. 19 is a perspective view showing a structure of a GaN-based semiconductor laser chip according to a second modification of the first embodiment of the present invention;

FIG. 20 is a perspective view showing a structure of a GaN-based semiconductor laser chip according to a third modification of the first embodiment of the present invention; and

FIG. 21 is a perspective view showing a structure of a GaN-based semiconductor laser chip according to a fourth modification of the first embodiment of the present invention.

### DESCRIPTION OF THE PREFERRED EMBODIMENTS

### First Embodiment

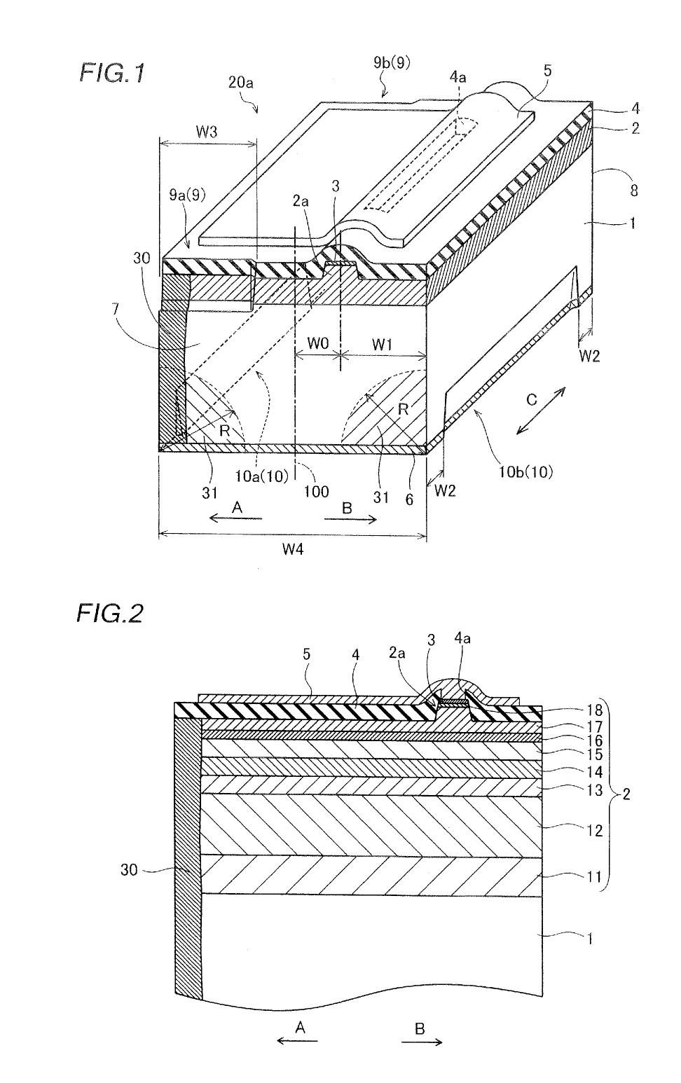

An exemplary structure formed by a process of fabricating a GaN-based semiconductor laser chip according to a first embodiment (semiconductor laser chip 20a) will be now described with reference to FIGS. 1 and 2. The GaN-based semiconductor laser chip according to the first embodiment is a semiconductor laser chip (blue-violet laser diode) having a lasing wavelength of a 400 nm band.

As shown in FIG. 1, the exemplary semiconductor laser chip 20a according to the first embodiment includes an active layer 14 (see FIG. 2) described later on an n-type GaN substrate 1 and is formed with a nitride-based semiconductor layer 2 having a p-n junction. The n-type GaN substrate 1 is an example of the “substrate” in the present invention.

As shown in FIG. 1, the exemplary semiconductor laser chip 20a according to the first embodiment is formed with a linear defect concentration region 30 having a large number of defects on first ends (ends along arrow A) of the n-type GaN substrate 1 and the semiconductor layer 2. This n-type GaN substrate 1 is a substrate reducing the number of defects in a wide region other than the prescribed region (defect concentration region 30) by forming the defects in the prescribed region in a concentrated manner. The semiconductor layer 2 is an example of the “nitride-based semiconductor layer” in the present invention.

The length (width) along arrow A (along arrow B) of the semiconductor laser chip 20a is about 200 μm and the length (depth) along arrow C substantially perpendicular to arrow A (arrow B) is about 400 μm. A cleavage direction (direction substantially perpendicular to a direction in which an after-mentioned ridge portion 2a extends (direction C))(along arrow A (along arrow B)) is a <11-20> direction. A plane from which a laser beam is emitted (cleavage plane 7 or 8 described later) is an M plane ({1-100} plane).

As shown in FIG. 1, the semiconductor layer 2 includes the ridge portion 2a constituting a light waveguide extending in the direction C in a striped (slender) manner. According to the first embodiment, this ridge portion 2a is formed on a region close to a second side (side along arrow B) from a center 100 along arrow A (along arrow B) of the semiconductor laser chip 20a (n-type GaN substrate 1) by a distance W0 (=about 20 μm). In other words, the ridge portion 2a is formed at a position separating from the defect concentration region 30 by about 120 μm. The ridge portion 2a is formed inside from a second end (end along arrow B) of the semiconductor laser chip 20a (n-type GaN substrate 1) by a prescribed distance W1 (=about 80 μm). A p-side electrode 3 obtained by successively stacking a Pt film and a Pd film from a side of the ridge portion 2a (lower side) is formed on an upper surface of the ridge portion 2a. A current blocking layer 4 of SiO₂ having a thickness of about 300 nm is so formed on the semiconductor layer 2 as to cover the p-side electrode 3. An opening 4a is provided on a region other than the vicinity of both ends (cleavage planes 7 and 8 described later) in the direction C of the current blocking layer 4 directly above the p-side electrode 3.

A p-side pad electrode 5 obtained by successively stacking a Ti film and an Au film from sides of the p-side electrode 3 and the current blocking layer 4 (lower side) is formed on a region surrounded by a line inside from facets (four sides) of the semiconductor laser chip 20a (n-type GaN substrate 1) on the p-side electrode 3 and the current blocking layer 4 by about 30 μm. In other words, the p-side pad electrode 5 is electrically connected to the p-side electrode 3 through the opening 4a. The p-side pad electrode 5 is an example of the “second electrode layer” in the present invention. The length (width) along arrow A (along arrow B) of the p-side pad electrode 5 is about 140 μm and the length (depth) in the direction C is about 340 μm. An n-side electrode 6 obtained by successively stacking a Ti film, a Pt film and an Au film from a side of the n-type GaN substrate 1 (upper side) is formed on a back surface of the semiconductor laser chip 20a (n-type GaN substrate 1). The n-side electrode 6 is an example of the “first electrode layer” in the present invention.

The two cleavage planes 7 and 8 are formed perpendicular to the ridge portion 2a constituting the light waveguide on the semiconductor laser chip 20a (see FIG. 1). The cleavage planes 7 and 8 are examples of the “divided surfaces by a first division” in the present invention. These two cleavage planes 7 and 8 constitute cavity planes. The cleavage planes 7 and 8 are formed with a facet coat film (not shown) of SiO₂ having a thickness of about 105 nm and a facet coat film (not shown) obtained by alternately staking five SiO₂ films each having a thickness of about 70 nm and five TiO₂ films each having a thickness of about 43 nm.

In the exemplary semiconductor laser chip 20a according to the first embodiment, cleavage introducing step portions 9a and 9b for performing cleavage (first division), having a depth of about 40 μm reaching the inside of the substrate 1 from the upper surface side (current blocking layer 4 side) are formed on the n-type GaN substrate 1, the semiconductor layer 2 and the current blocking layer 4. The cleavage introducing step portions 9a and 9b are formed on regions where the p-side pad electrode 5 is not formed The cleavage introducing step portions 9a and 9b are examples of the “second step portions” in the present invention.

According to the first embodiment the cleavage introducing step portions 9a and 9b of the semiconductor laser chip 20a are formed on regions including the defect concentration region 30 having a large number of defects and not including the ridge portion 2a (light waveguide). More specifically, the cleavage introducing step portions 9a and 9b are so formed on only a first region (region along arrow A) of the ridge portion 2a as to extend along a direction (along arrow A (along arrow B)) perpendicular to the ridge portion 2a (light waveguide) up to the first ends (ends along arrow A) of the semiconductor laser chip 20a (n-type GaN substrate 1), as shown in FIG. 1. The cleavage introducing step portions 9a and 9b each are formed such that a width W3 along arrow A (along arrow B) is at least 1/20 of a width W4 of the semiconductor laser chip 20a (width along arrow A (along arrow B) of the cleavage plane 7 or 8) (=about 200 μm) along arrow A (along arrow B) of the cleavage plane 7 or 8.

According to the first embodiment, division introducing step portions 10a and 10b for dividing into chips (second division) along a direction (direction C) in which the ridge portion 2a (light waveguide) extends from a back surface side (side opposite to a side where the semiconductor layer 2 is formed) of the semiconductor laser chip 20a (n-type GaN substrate 1) are formed on ends along arrows A and B of the n-type GaN substrate 1 and the n-side electrode 6. The division introducing step portions 10a and 10b each have a depth of about 40 μm reaching the inside of the substrate 1 from the n-side electrode 6 side. The division introducing step portions 10a and 10b are examples of the “first step portions” in the present invention.

According to the first embodiment, the division introducing step portions 10a and 10b are formed on regions spaced at prescribed distances W2 (=about 20 μm) from the cleavage planes 7 and 8 extending along arrow A (along arrow B) as shown in FIG. 1. The division introducing step portions 10a and 10b each are formed such that the length (=about 360 μm) along arrow C is at least ⅕ of the length (=about 400 μm) in the direction C of the semiconductor laser chip 20a. The division introducing step portions 10a and 10b are formed by irradiation of the laser beam and materials of the n-type GaN substrate 1 and the n-side electrode 6 powdered by evaporation (debris 31) due to the irradiation of the laser beam adhere to lower portions of the cleavage planes 7 and 8. The debris 31 each are so formed as to have a prescribed radius R about 80 μm) about the lower portions of the cleavage planes 7 and 8 in the vicinity of the division introducing step portions 10a and 10b.

According to detailed structures of the n-type GaN substrate 1 and the semiconductor layer 2, the n-type GaN substrate 1 is doped with oxygen and has a hexagonal structure. The semiconductor layer 2 has a surface (upper surface) constituted by a C plane ((0001) plane) of a Ga plane. As shown in FIG. 2, the semiconductor layer 2 is arranged on the n-type GaN substrate 1 and formed with a buffer layer 11 constituted by an n-type GaN layer doped with Si. An n-type cladding layer 12 of n-type Al_{0.05}Ga_{0.95}N is formed on the buffer layer 11.

An n-side light guide layer 13 of undoped GaN is formed on the n-type cladding layer 12. An active layer 14 having a multiple quantum well (MQW) is formed on the n-side light guide layer 13. The active layer 14 has a structure obtained by alternately stacking two barrier layers (not shown) of undoped GaN and three well layers (not shown) of undoped In_{0.1}Ga_{0.9}N.

A p-side light guide layer 15 of undoped GaN is formed on the active layer 14. A cap layer 16 of undoped Al_{0.3}Ga_{0.7}N is formed on the p-side light guide layer 15. The cap layer 16 has a function of inhibiting the active layer 14 from deterioration of crystal quality by inhibiting desorption of In atoms forming the active layer 14.

A p-type cladding layer 17 of p-type Al_{0.05}Ga_{0.95}N doped with Mg is formed on the cap layer 16. The p-type cladding layer 17 has a width of about 1.5 μm formed by etching a prescribed region from an upper surface of the p-type cladding layer 17 and has a projecting portion extending in the direction C (see FIG. 1). A p-side contact layer 18 of undoped In_{0.05}Ga_{0.95}N is formed on the projecting portion of the p-type cladding layer 17. The projecting portion of the p-type cladding layer 17 and the p-side contact layer 18 form the ridge portion 2a forming a current injection region and constituting the light waveguide.

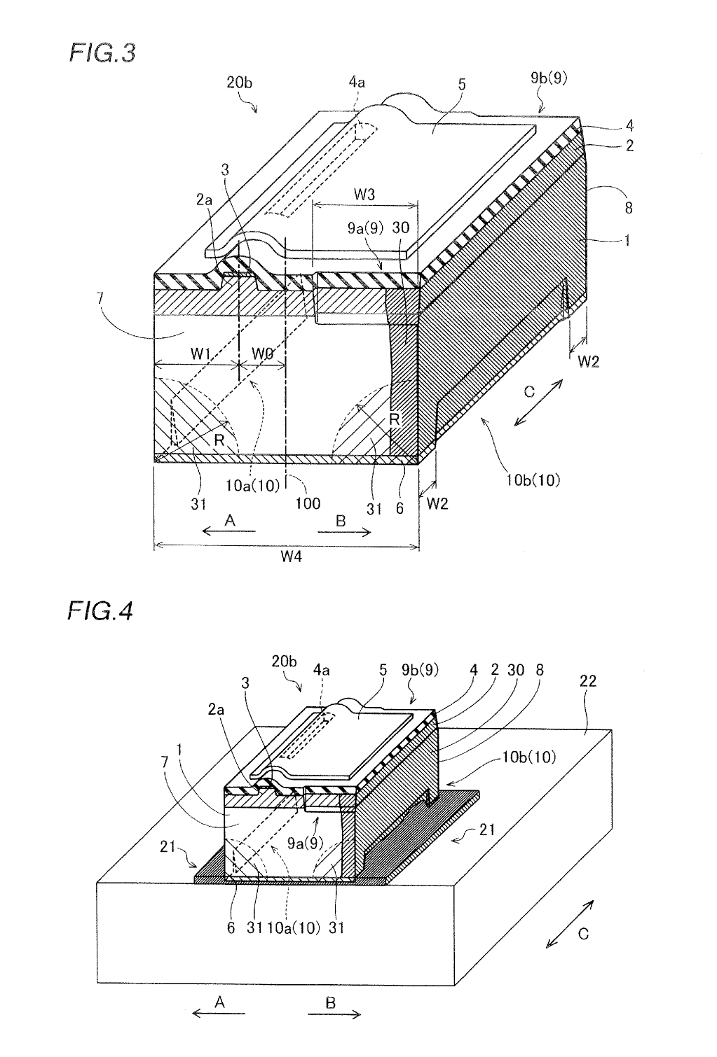

Another exemplary structure formed through the process of fabricating the GaN-based semiconductor laser chip according to the first embodiment (semiconductor laser chip 20b) will be now described with reference to FIGS. 3 and 4.

According to the first embodiment, another exemplary semiconductor laser chip 20b according to the first embodiment as shown in FIG. 3 is also formed in addition to the exemplary semiconductor laser chip 20a according to the first embodiment shown in FIG. 1, in the fabricating process described later. The semiconductor laser chip 20b has a shape symmetrical to the semiconductor laser chip 20a (see FIG. 1) along arrow A (along arrow B) with respect to the center 100 as a symmetrical axis.

FIG. 4 shows a structure in which an n-side electrode 6 side of another exemplary semiconductor laser chip 20b (n-type GaN substrate 1) according to the first embodiment is fixed on a radiator base (submount) 22 of AlN through solder 21 of Au—Sn in a junction-up system. At this time, the fused solder 21 flows not only on a back surface side of the n-side electrode 6 of the semiconductor laser chip 20b but also flows into so as to conform shapes of the division introducing step portions 10a and 10b for being firmly fixed on the radiator base 22, and hence the semiconductor laser chip 20b is reliably fusion bonded on the radiator base 22. The solder 21 is an example of the “fusion layer” in the present invention.

While the another exemplary semiconductor laser chip 20b according to the first embodiment is fusion bonded on the radiator base 22 in the junction-up system in FIG. 4, the exemplary semiconductor laser chip 20a (see FIG. 1) according to the first embodiment can be also fusion bonded on the radiator base 22 in the junction-up system similarly to the above.

A process of fabricating the semiconductor laser chips 20a and 20b according to the first embodiment in a wafer state (wafer process) will be now described with reference to FIGS. 1 to 6.

As shown in FIG. 2, the buffer layer 11 of the n-type GaN layer doped with Si, the n-type cladding layer 12 of n-type Al_{0.05}Ga_{0.95}N and the n-side light guide layer 13 of undoped GaN are successively grown on the n-type GaN substrate 1 having the defect concentration region 30 at a substrate temperature of about 1150° C. by MOVPE (metal organic vapor phase epitaxy).

According to the first embodiment, a substrate provided with a plurality of the defect concentration region 30 extending in the direction C and arranged in the form of a strip at intervals of about 400 μm along arrow A (along arrow B) is employed as the n-type GaN substrate 1.

Thereafter three well layers (not shown) of undoped In_{0.1}Ga_{0.9}N and two barrier layers (not shown) of undoped GaN are alternately grown on the n-side light guide layer 13 at a substrate temperature of about 850° C. by MOVPE, thereby forming the active layer 14. Then, the p-side light guide layer 15 of undoped GaN and the cap layer 16 of undoped Al_{0.3}Ga_{0.7}N are successively formed on the active layer 14.

Thereafter the p-type cladding layer 17 of p-type Al_{0.05}Ga_{0.95}N doped with Mg is grown on the cap layer 16 at a substrate temperature of about 1150° C. by MOVPE.

The p-side contact layer 18 of undoped In_{0.05}Ga_{0.95}N is formed on the p-type cladding layer 17 at a substrate temperature of about 850° C. by MOVPE.

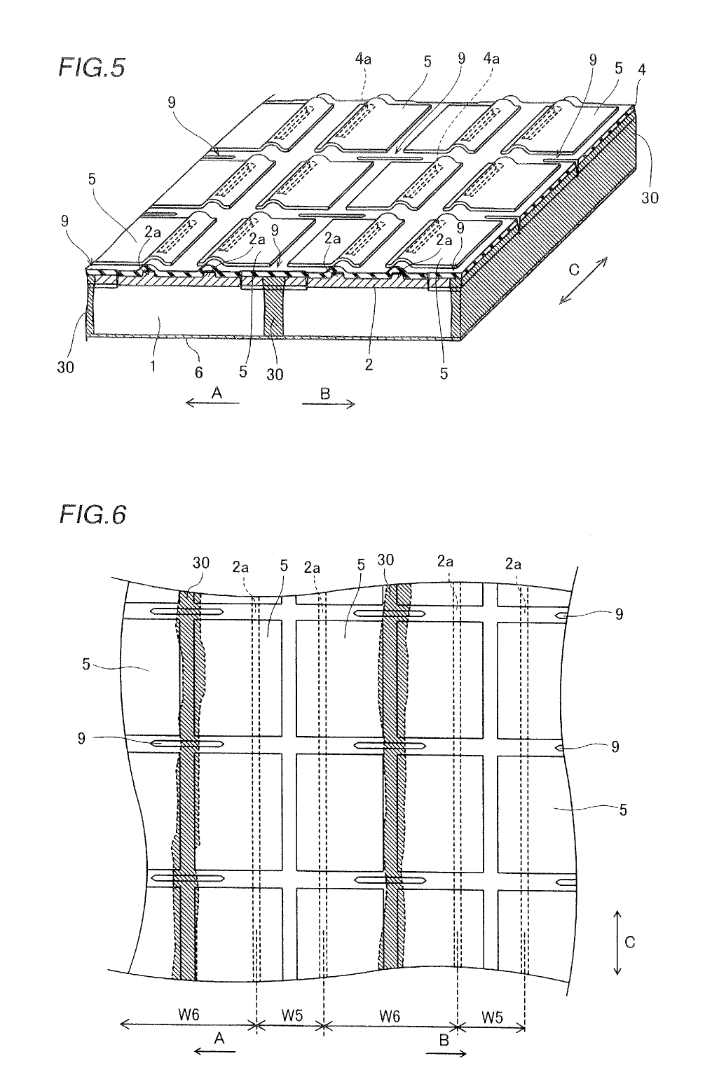

Thereafter the ridge portion 2a and the p-side electrode 3 are formed by vacuum evaporation and etching. More specifically, the Pt film and the Pd film are successively formed on the p-side contact layer 18 from the p-side contact layer 18 (lower side) by vacuum evaporation. Then resists (not shown) extending in the direction C (see FIG. 1) are employed as masks for etching the Pt film and the Pd film and etching prescribed regions from the upper surfaces of the p-side contact layer 18 and the p-type cladding layer 17 by etching. Thus, the ridge portions 2a constituted by the p-side contact layers 18 and the projecting portions of the p-type cladding layer 17, having widths of about 1.5 μm and having functions as the current injection regions and the light waveguides and the p-side electrodes 3 arranged on the ridge portions 2a are formed. At this time, the ridge portions 2a are so formed at intervals of about 200 μm as to extend in the direction (<1-100> direction) (direction C) substantially perpendicular to the <11-20> direction (along arrow A (along arrow B)) as the cleavage direction in the striped (slender) manner, as shown in FIGS. 5 and 6.

According to the first embodiment, pairs of the ridge portions 2a are formed between the adjacent defect concentration regions 30 extending in the direction C. As shown in FIG. 6, the ridge portions 2a are so formed as Lo alternately have two different prescribed intervals W5 (=about 160 μm) and W6 (=about 240 μm). In other words, according to the first embodiment, the distances from the centers of the ridge portions (light waveguide) 2a to the ridge portions (light waveguide) 2a (about 80 μm) are at most the distances from the defect concentration regions 30 to the ridge portions (light waveguide) 2a (about 120 μm).

Thus, the semiconductor layer 2 constituted by the buffer layer 11, the n-type cladding layer 12, the n-side light guide layer 13, the active layer 14, the p-side light guide layer 15, the cap layer 16, the p-type cladding layer 17 and the p-side contact layer 18 is formed as shown in FIG. 2. At this time, according to the first embodiment, regions of the semiconductor layer 2 formed on the defect concentration regions 30 having a large number of defects of the n-type GaN substrate 1 are also the defect concentration regions 30 having a large number of defects.

Thereafter the current blocking layer 4 of SiO₂ having a thickness of about 300 nm is so formed on the semiconductor layer 2 as to cover the p-side electrodes 3 by plasma CVD as shown in FIG. 1.

Photoresist (not shown) are employed as masks for etching the current blocking layer 4 by etching, thereby forming the openings 4a on portions of the current blocking layer 4 other than the vicinity of cleavage plane forming regions among the regions directly above the p-side electrodes 3. Thus, the upper surfaces of the p-side electrodes 3 are exposed.

Thereafter the Ti film and the Au film are successively stacked on the prescribed regions of the p-side electrodes 3 and the current blocking layer 4 from the p-side electrodes 3 and the current blocking layer 4 (lower side) by vacuum evaporation and a lift-off method, thereby forming the p-side pad electrodes 5. More specifically, the photoresists (not shown) are formed on regions (regions up to about 30 μm from the positions forming the facets) other than regions surrounded by lines inside from positions forming the facets (four sides) of the GaN-based semiconductor laser chips (n-type GaN substrate 1) on the current blocking layer 4 by about 30 μm. The Ti film and the Au film are successively formed on the p-side electrodes 3 and the current blocking layer 4 from the sides of the p-side electrodes 3 and the current blocking layer 4 by vacuum evaporation. Thereafter the photoresists (not shown) are removed by the lift-off method, whereby the p-side pad electrodes 5 are formed on the regions (regions other than the regions up to about 30 μm from the positions forming the facets) surrounded by the lines inside from the positions forming the facets (four sides) of the GaN-based semiconductor laser chips (n-type GaN substrate 1) on the p-side electrodes 3 and the current blocking layer 4 by about 30 μm. At this time, in the p-side pad electrodes 5, the centers along arrow A (along arrow B) of the p-side pad electrodes 5 are arranged on the regions close to the side along arrow A or B from the ridge portions 2a constituting the light waveguides by about 20 μm as shown in FIG. 5. Each p-side pad electrode 5 is formed such that the length (width) along arrow A (along arrow B) is about 140 μm and the length (depth) in the direction C is about 340 μm.

The back surface of the n-type GaN substrate 1 is polished until the thickness of the n-type GaN substrate 1 reaches about 130 μm, for example.

Thereafter the Ti film, the Pt film and the Au film are successively stacked on the back surface of the n-type GaN substrate 1 from the n-type GaN substrate 1 side (upper side) by vacuum evaporation, thereby forming the n-side electrode 6.

As described above, a wafer where the GaN-based semiconductor laser chips are arranged in the form of a matrix is completed.

A process of fabricating the GaN-based semiconductor laser chips according to the first embodiment subsequent to the wafer process (process of fabricating chips) will be now described with reference to FIGS. 1 and 5 to 10.

As shown in FIG. 5, cleavage grooves 9 extending in a direction (along arrows A and B) perpendicular to the ridge portions 2a are formed from the semiconductor layer 2 (upper side) at intervals of about 400 μm along the direction (direction C) in which the striped ridge portions 2a extend by laser beam. At this time, the cleavage grooves 9 each having a length of about 100 μm are formed only between the ridge portions (light waveguides) 2a with the larger intervals W6 (=about 240 μm) therebetween among the two different intervals (see FIG. 6). In other words, according to the first embodiment, the cleavage grooves 9 are formed on the regions including the defect concentration regions 30 and not including the ridge portions (light waveguides) 2a in a broken line fashion extending along arrow A (along arrow B) at every defect concentration region 30.

The cleavage grooves 9 each are so formed as to have a depth of about 40 μm and formed in the n-type GaN substrate 1, the semiconductor layer 2, and the current blocking layer 4 from the upper surface of the GaN-based semiconductor laser chip.

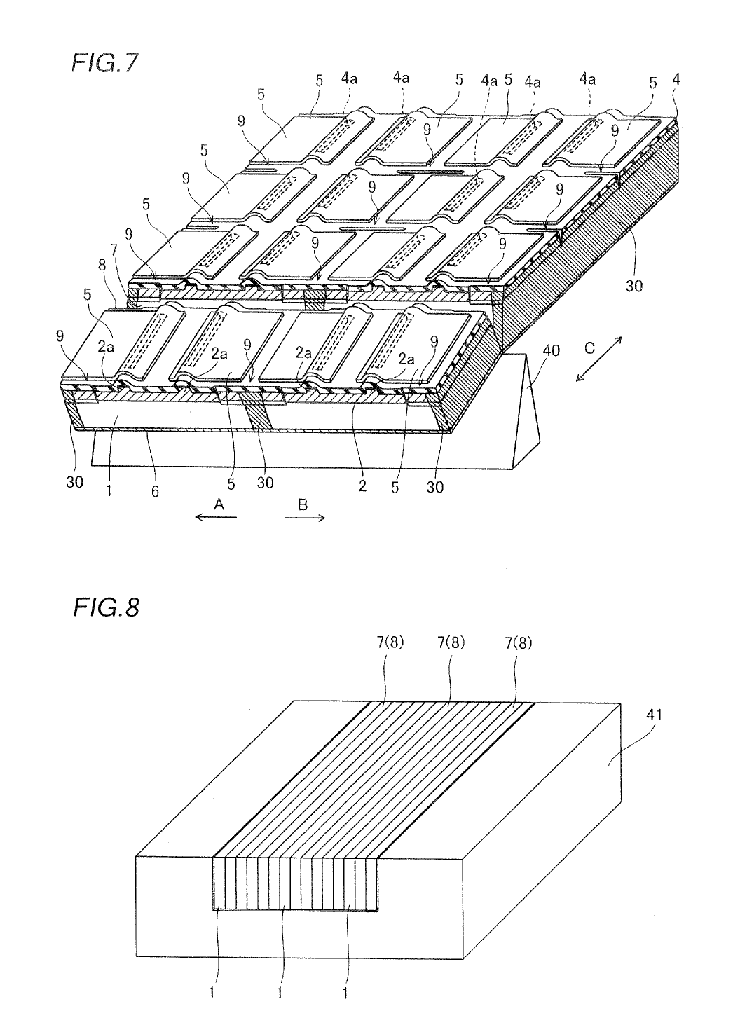

In this state, as shown in FIG. 7, an edged tool 40 extending along arrow A (along arrow B) is brought into contact with the wafer from the lower surface side along the cleavage grooves 9 and a load is applied to open an upper surface of the wafer, so that the wafer is cleaved at a position of the cleavage grooves 9 along arrow A (along arrow B) (first division). Thus, the wafer is formed in the form of a bar where the semiconductor laser chips 20a and 20b are alternately arranged in a row along arrow A (along arrow B).

As shown in FIG. 8, a plurality of the wafers cleaved in the form of a bar are arranged on a facet coating tool 41 such that the cleavage planes 7 are upper sides. Facet coat films (not shown) of SiO₂ each having a thickness of about 105 nm are formed on the cleavage planes 7. Thereafter the plurality of wafers cleaved in the form of a bar are turned over and arranged on the facet coating tool 41 such that the cleavage planes 8 are upper sides. Facet coat films (not shown) obtained by alternately stacking five SiO₂ films each having thickness of about 70 nm and five TiO₂ films each having a thickness of about 43 nm are formed on the cleavage planes 8. Thus, the cavity planes are formed on the cleavage planes 7 and 8.

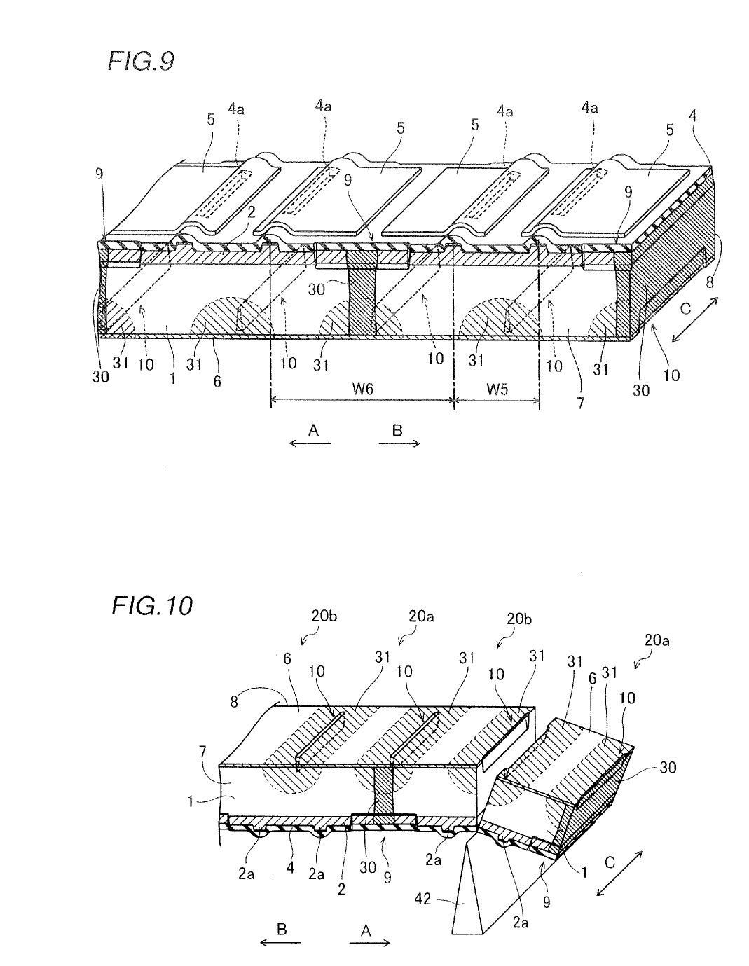

As shown in FIG. 9, element dividing grooves 10 each having a depth of about 40 μm are formed in the direction (direction C) in which the striped ridge portions 2a extend from the back surface of the n-type GaN substrate 1 of each wafer cleaved in the form of a bar at intervals of about 200 μm with laser beam in a non-contact state.

At this times according to the first embodiment, the element dividing grooves 10 are formed on regions spaced at the prescribed distances W2 (about 20 μm) (see FIG. 1) from the cleavage planes 7 and 8 extending along arrow A (along arrow B). At this time, the debris 31 (materials of the n-type GaN substrate 1 and the n-side electrode 6 powdered by evaporation) each having the prescribed radius R (=about 80 μm) adhere to the lower portions of the cleavage planes 7 and 8 due to the irradiation of the laser beam. The element dividing grooves 10 are formed on the n-type GaN substrate 1 with laser beam in the non-contact state, and hence breaks or cracks can be inhibited from occurring in the semiconductor layer 2 when forming the element dividing grooves 10.

According to the first embodiment, the element dividing grooves 10 are formed on centers between the ridge portions (light waveguides) 2a with the intervals W5 (see FIG. 6) of about 160 μm therebetween and centers between the ridge portions (light waveguides) 2a with the intervals W6 (see FIG. 6) of about 240 μm therebetween. In other words, according to the first embodiment, the element dividing grooves 10 are formed on the defect concentration regions 30 and the centers between the ridge portions (light waveguides) 2a with the intervals W5 (see FIG. 6) of about 160 μm therebetween.

In this state, as shown in FIG. 10, an edged tool 42 extending in the direction C is brought into contact with the wafer in the form of a bar from the upper surface side (semiconductor layer 2 side) along each element dividing groove 10 and a load is applied to open a lower surface (n-side electrode 6 side) of the wafer in the form of a bar, so that the wafer in the form of a bar is divide at a position of the element dividing groove 10 along the direction C (second division). Thus, the wafer in the form of a bar is divided into the GaN-based semiconductor laser chips each having the length (width) along arrow A (along arrow B) of about 200 μm and the length (depth) in the direction C of about 400 μm, and a large number of the GaN-based semiconductor laser chips (semiconductor laser chips 20a and 20b) are fabricated as shown in FIG. 1.

As shown in FIG. 4, the semiconductor laser chip 20b chipped through the aforementioned fabricating process placed with the n-side electrode 6 down is fusion bonded to the radiator base (submount) 22 through the solder 21 heated at a high temperature. At this time, the fused solder 21 flows not only on the back surface side of the n-side electrode 6 of the semiconductor laser chip 20b but also flows into so as to conform shapes of the division introducing step portions 10a and 10b for being firmly fixed on the radiator base 22. Thus, the GaN-based semiconductor laser chip in the junction-up system is formed.

According to the first embodiment, as hereinabove described, the division introducing step portions 10a and 10b (element dividing grooves 10) so formed as to extend in the direction C by irradiation of the laser beam are provided on the n-side electrode 6 side opposite to the side on which the semiconductor layer 2 of the n-type GaN substrate 1 is formed, whereby the division introducing step portions 10a and 10b (element dividing grooves 10) are formed at positions separating from the semiconductor layer 2 on the n-type GaN substrate 1 and hence breaks or cracks can be inhibited from occurring in the semiconductor layer 2. Thus, the ridge portion 2a constituting the light waveguide of the semiconductor layer 2 can be inhibited from being damaged.

According to the first embodiment, the division introducing step portions 10a and 10b (element dividing grooves 10) formed by irradiation of the laser beam are provided on the regions spaced at prescribed distances W2 (=about 20 μm) from the cleavage planes 7 and 8 of the n-type GaN substrate 1, whereby the element dividing grooves 10 can be formed at the positions separating from the cleavage planes 7 and 8 including the facets of the ridge portions (light waveguides) 2a, and hence the debris 31 (materials of the n-type GaN substrate 1 and the n-side electrode 6 powdered by evaporation) can be inhibited from adhering in the vicinity of the facets including the ridge portions 2a when forming the division introducing step portions 10a and 10b (element dividing grooves 10) by irradiation of the laser beam. Thus, intensity of the laser beam emitted from the emission point under the ridge portion 2a can be inhibited from reduction. The division introducing step portions 10a and 10b (element dividing grooves 10) formed by irradiation of the laser beam are provided on the n-side electrode 6 side opposite to the side on which the semiconductor layer 2 of the n-type GaN substrate 1 is formed, whereby the division introducing step portions 10a and 10b (element dividing groove) are further separated from the ridge portion 2a of the semiconductor layer 2 and hence the debris 31 can be inhibited from adhering in the vicinity of the facets of the ridge portions 2a when forming the division introducing step portions 10a and 10b (element dividing grooves 10) due to irradiation of the laser beam. Thus, intensity of light emitted from the emission point under the ridge portion 2a can be inhibited from reduction.

According to the first embodiment, the distance W1 (=about 80 μm) from the center between the ridge portions (light waveguides) to the ridge portion 2a is at most the distance from the defect concentration region 30 to the ridge portion 2a (about 120 μ), whereby the ridge portion 2a can be formed at the position separating from the defect concentration region 30. In a case where the division introducing step portions 10a and 10b (element dividing grooves 10) are formed by irradiation of the laser beam, light absorption increases in the defect concentration region 30, thereby likely to result in a high temperature, and hence formation of the ridge portion 2a at the position separating from the defect concentration region 30 can inhibit the temperature from excessively rising in the ridge portion 2a. Thus, the ridge portion (light waveguide) 2a can be inhibited from being damaged when forming the division introducing step portions 10a and 10b (element dividing grooves 10).

According to the first embodiment, the lengths along arrow C of the division introducing step portions 10a and 10b (element dividing grooves 10) each are so formed as to have at least ⅕ of the distance between the facets of the ridge portion (light waveguide) along arrow C, whereby the element dividing grooves 10 are previously formed on the long regions each having at least ⅕ of the distance between the facets of the ridge portion 2a when performing a device division along arrow C and hence the device division can be easily performed along arrow C staring at the element dividing grooves 10. Thus, breaks or cracks can at be inhibited from occurring in the semiconductor layer 2.

According to the first embodiment, the division introducing step portions 10a and 10b (element dividing grooves 10) each are so formed as to have the depth reaching the inside of the n-type GaN substrate 1 from the n-side electrode 6 side, whereby not only the n-side electrode 6 but also the n-type GaN substrate 1 can be easily divided at the step of performing the device division along the element dividing grooves 10

According to the first embodiment, the cleavage introducing step portions 9a and 9b (cleavage grooves 9) formed in the broken line fashion are so formed on the regions including the defect concentration regions 30 and not including the ridge portions (light waveguides) 2a by irradiation of the laser beam as to extend along arrow A (along arrow B) every defect concentration region 30, whereby cleavage can be performed without forming the cleavage introducing step portions 9a and 9b (cleavage grooves 9) on the ridge portion 2a and hence the divided surfaces of the ridge portion 2a can easily form the cleavage plane.

According to the first embodiment, the widths W3 of the cleavage introducing step portions 9a and 9b (cleavage grooves 9) along arrow A (along arrow B) are so formed as to have at least 1/20 of the width W4 of the semiconductor laser chip 20a (20b) (width along arrow A (along arrow B) of the cleavage plane 7 or 8) (=about 200 μm), whereby the cleavage grooves 9 are previously formed on the long region having at least 1/20 of the width W4 of the semiconductor laser chip 20a (20b) (width along arrow A (along arrow B) of the cleavage plane 7 or 8) when performing cleavage along arrow A (along arrow B) and hence the cleavage can be easily performed along arrow A (along arrow B) starting from the cleavage grooves 9.

According to the first embodiment, the cleavage introducing step portions 9a and 9b (cleavage grooves 9) each are so formed as to have the depth reaching the inside of the n-type GaN substrate 1 from the semiconductor layer 2 side, whereby not only the semiconductor layer 2 but also the n-type GaN substrate 1 can be easily divided when performing cleavage along the cleavage grooves 9.

According to the first embodiment, the p-side electrode 3 is formed on the region surrounded inside from the cleavage introducing step portions 9a and 9b (facets of the semiconductor laser chips 20a and 20b) by about 30 μm, whereby the p-side electrode 3 is formed at prescribed intervals from the cleavage grooves 9 and hence a leak current can be inhibited from increase due to adherence of a conductive material constituting the p-side electrode 3 to the cleavage grooves 9 also in a case where the conductive material is scattered by irradiation of the laser beam when forming the cleavage grooves 9.

According to the first embodiment, the n-side electrode 6 side of the n-type GaN substrate 1 is fixed on the radiator base 22 through the solder 21 of Au—Sn, whereby the solder 21 is not only firmly fixed on the back surface of the n-side electrode 6 but also intrudes in the recessed division introducing step portions 10a and 10b from the back surface for firmly fixing and hence the semiconductor laser chip 20b can be stably fixed on the radiator base 22. Consequently, axial deviation of laser emission light can be inhibited. Also in a case where the semiconductor laser chip 20a (see FIG. 1) is fusion bonded on the radiator base 22 in the junction-up system, effects similar to the above is obtained.

### First Modification of First Embodiment

In a GaN-based semiconductor laser chip according to a first modification of the first embodiment, the aforementioned exemplary semiconductor laser chip 20a according to the first embodiment is fixed on a radiator base 22 in a junction-down system, dissimilarly to the aforementioned first embodiment.

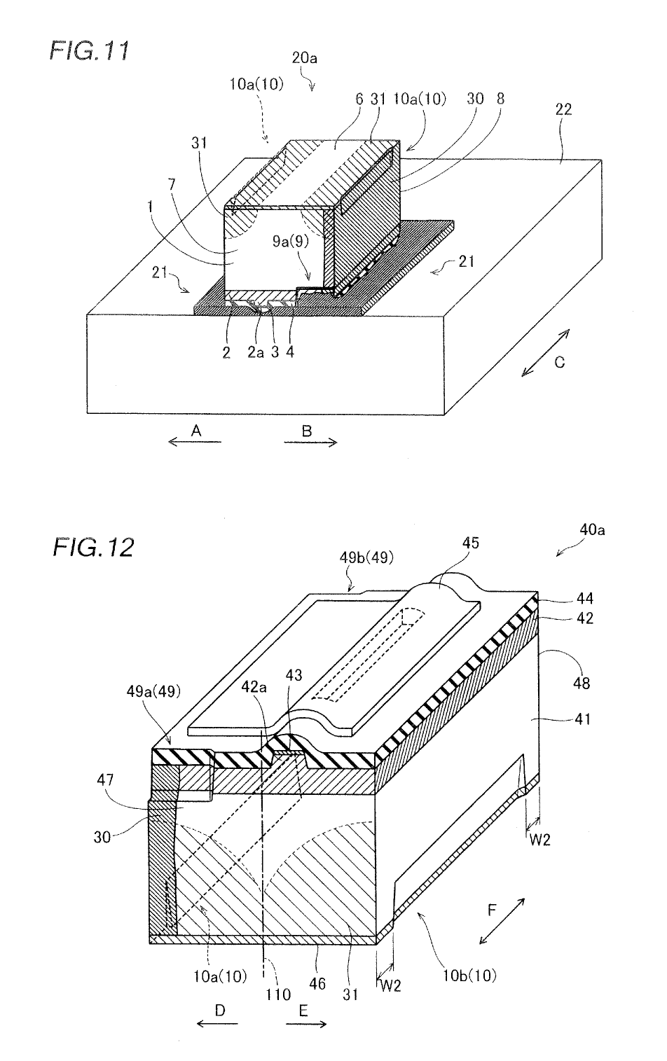

According to the first modification of the first embodiment, a p-side pad electrode 5 side of the semiconductor laser chip 20a (n-type GaN substrate 1) is fixed on a radiator base 22 of AlN through solder 21 of Au—Sn in the junction-down system, as shown in FIG. 11. In this case, the fused solder 21 flows not only on a surface of the p-side pad electrode 5 of the semiconductor laser chip 20a but also flows into so as to conform shapes of cleavage introducing step portions 9a and 9b formed on sides closer to a semiconductor layer 2 of cleavage planes 7 and 8 for being firmly fixed on the radiator base 22, and hence the semiconductor laser chip 20a is reliably fusion bonded on the radiator base 22.

According to the first modification of the first embodiment, as hereinabove described, the p-side pad electrode 5 side formed with the semiconductor layer 2 of the n-type GaN substrate 1 is fixed on the radiator base 22 through the solder 21 of Au—Sn, whereby the solder 21 is not only firmly fixed on the surface of the p-side pad electrode 5 but also intrudes in the cleavage introducing step portions 9a and 9b for firmly fixing and hence the semiconductor laser chip 20a can be stably fixed on the radiator base 22. Consequently, axial deviation of laser emission light can be inhibited. The fused solder 21 intrudes in the cleavage introducing step portion 9a (see FIG. 11) for firmly fixing and hence does not stick out in the vicinity of the ridge portion (light waveguide) 2a of a cavity facet (cleavage plane 7). Thus, the solder 21 can be inhibited from hindering laser emission light from the ridge portion 2a.

The remaining effects of the first modification of the first embodiment are similar to those of the aforementioned first embodiment. Also in a case where the aforementioned another exemplary semiconductor laser chip 20b (see FIG. 3) according to the first embodiment is fusion bonded on the radiator base 22 in the junction-down system, effects similar to the above is obtained.

### Second Embodiment

Referring to FIGS. 12 to 14, according to a second embodiment, three GaN-based semiconductor laser chips are formed between defect concentration regions adjacent to each other dissimilarly to the aforementioned first embodiment.

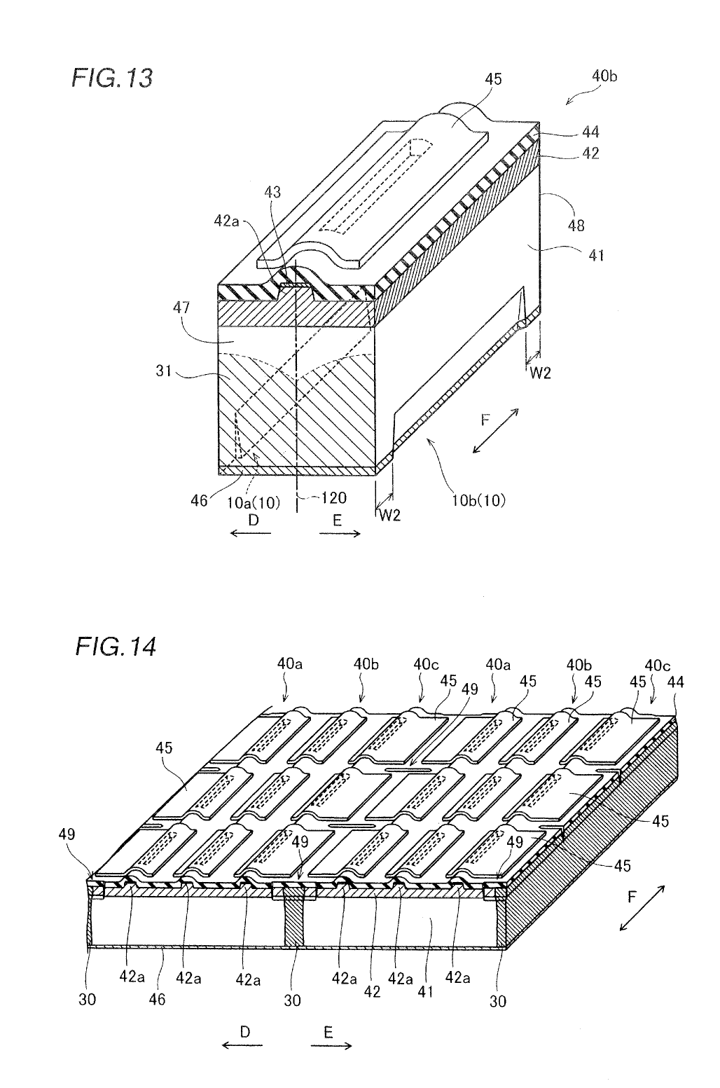

The GaN-based semiconductor laser chips according to the second embodiment are constituted by an semiconductor laser chip 40a having a defect concentration region 30 with a large number of defects on a first side (side along arrow D or E) of an n-type GaN substrate 41 and a semiconductor laser chip 40b not having the defect concentration region 30 with a large number of defects on the n-type GaN substrates as shown in FIGS. 12 and 13. A semiconductor laser chip 40c as shown in FIG. 14 is also formed in addition to the semiconductor laser chip 40a according to the second embodiment shown in FIG. 12, in the fabricating process described later. The semiconductor laser chip 40c has a shape symmetrical to the semiconductor laser chip 40a (see FIG. 12) along arrow D (along arrow E) with respect to a center 110 as a symmetrical axis similarly to the semiconductor laser chip 20b with respect to the semiconductor laser chip 20a according to the first embodiment.

The semiconductor laser chips 40a (40c) and 40b are so formed as to have lengths along arrow D (along arrow E) of about 150 μm and about 100 μm respectively, as shown in FIGS. 12 and 13. The n-type GaN substrate 41 is an example of the “substrate” in the present invention.

The semiconductor laser chips 40a (40c) and 40b are formed with nitride-based semiconductor layers 42 including ridge portions 42a constituting light waveguides extending in a direction F in a striped (slender) manner on the n-type GaN substrates 41 similarly to the aforementioned first embodiment Each semiconductor layer 42 is an example of the “nitride-based semiconductor layer” in the present invention. Current blocking layers 44 of SiO₂ each having a thickness of about 300 nm and p-side pad electrodes 45 are so formed on the semiconductor layers 42 as to cover p-side electrodes 43. Additionally, n-side electrodes 46 are formed on back surfaces of the n-type GaN substrates 41. The p-side pad electrode 45 and the n-side electrode 46 are examples of the “second electrode layer” and the “first electrode layer” in the present invention respectively Two cleavage planes 47 and 48 constituting cavity planes are formed perpendicular to the ridge portions 42a constituting the light waveguides. The cleavage planes 47 and 48 are examples of the “divided surfaces by a first division” in the present invention.

According to the second embodiment, in the semiconductor laser chip 40a, cleavage introducing step portions 49a and 49b (cleavage grooves 49) are formed on a first side and the ridge portion 42a is formed on a region close to a second side from the center 110 along arrow D (along arrow E) of the semiconductor laser chip 40a (n-type GaN substrate 41) as shown in FIG. 12, similarly to the aforementioned first embodiment. In the semiconductor laser chip 40b, no cleavage introducing step portions 49a and 49b (cleavage grooves 49) are formed and the ridge portion 42a is formed on a center 120 along arrow D (along arrow E) of the semiconductor laser chip 40b (n-type GaN substrate 41) as shown in FIG. 13, dissimilarly to the aforementioned first embodiment.

The remaining structure of the second embodiment is similar to that of the aforementioned first embodiment.

A process of fabricating the GaN-based semiconductor laser chips according to the second embodiment in a wafer state (wafer process) will be now described with reference to FIGS. 12 to 14.

As shown in FIGS. 12 and 13, the layers up to a p-side contact layer (not shown) are formed on the n-type GaN substrate 41 through a process similar to that of the aforementioned first embodiment. Thereafter the ridge portions (light waveguides) 42a and the p-side electrodes 43 are formed by vacuum evaporation and etching.

At this time, according to the second embodiment, the three ridge portions 42a are formed between the defect concentration regions 30 adjacent to each other as shown in FIG. 14.

The remaining fabrication process in the wafer state (wafer process) according to the second embodiment is similar to the fabricating process in the wafer state according to the aforementioned first embodiment.

A process of fabricating the GaN-based semiconductor laser chips according to the second embodiment subsequent to the wafer process (process of fabricating chips) will be now described with reference to FIGS. 12 to 14.

First, as shown in FIG. 14, the cleavage grooves 49 are formed on the regions including the defect concentration regions 30 and not including the ridge portions (light waveguides) 42a in a broken line fashion extending along arrow D (along arrow E) at every defect concentration region 30 through a process similar to that of the aforementioned first embodiment. In this state, the wafer is cleaved at a position of the cleavage grooves 49 along arrow D (along arrow E) (first division) through a process similar to that of the aforementioned first embodiment. Thus, the wafer is formed in the form of a bar where the GaN based-semiconductor laser chips are arranged in a row along arrow D (along arrow E).

Element dividing grooves 10 (see FIGS. 12 and 13) are formed in a direction in which the striped ridge portions 42a extend (direction F) from the back surface side of the n-type GaN substrate 41 of the wafer cleaved in the form of a bar through a process similar to that of the aforementioned first embodiment.

At this time, according to the second embodiment, the element dividing grooves 10 are formed on regions spaced at prescribed distances W2 (about 20 μm) from the cleavage planes 47 and 48 extending along arrow D (along arrow E) as shown in FIGS. 12 and 13 similarly to the aforementioned first embodiment.

According to the second embodiment, the element dividing grooves 10 are formed on the defect concentration regions 30 and portions separating from the defect concentration regions 30 by about 150 μm. In this state, the wafer in the form of a bar is divided at a position of the element dividing groove 10 along the direction F (second division), thereby fabricating a large number of GaN-based semiconductor laser chips (three kinds of semiconductor laser chips 40a (40c) and 40b) shown in FIGS. 12 and 13 through a process similar to that of the aforementioned first embodiment.

The remaining fabricating process subsequent to the wafer process (method of fabricating chips) of the second embodiment is similar to the fabricating process subsequent to the wafer process of the aforementioned first embodiment.

The effects of the second embodiment are similar to those of the aforementioned first embodiment. When the semiconductor laser chips 40a and 40c (see FIG. 12) are fixed on radiator bases through fusion layers (solders 21 or the like), the fusion layers intrude in the division introducing step portion 10a (10b) or the cleavage introducing step portion 49a (49b) for firmly fixing in either the junction-up system or junction-down system similarly to the aforementioned first embodiment, and hence the semiconductor laser chip 40a can be stably fixed on the radiator base When the semiconductor laser chip 40b (see FIG. 13) is fixed on the radiator base through the fusion layer, on the other hand, the fusion layer intrudes in the division introducing step portion 10a (10b) only in a case of the junction-down system for firmly fixing, and hence effects similar to the above is obtained.

### Third Embodiment

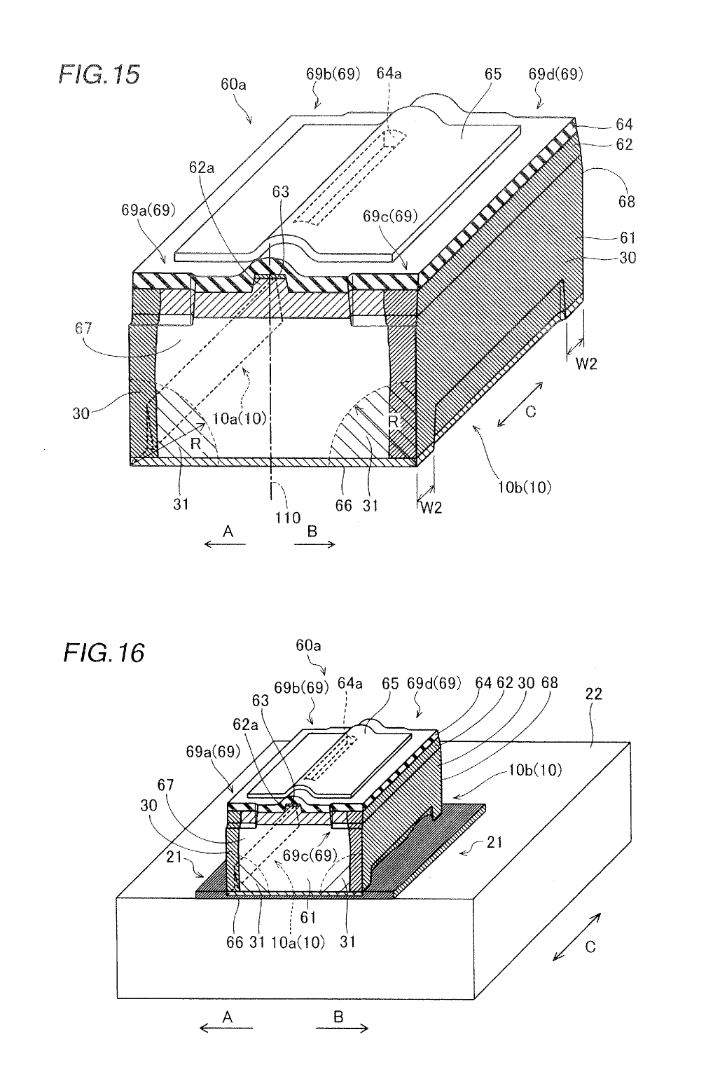

Referring to FIGS. 15 and 16, according to a third embodiment, one GaN-based semiconductor laser chip is formed between defect concentration regions adjacent to each other dissimilarly to the aforementioned first and second embodiments.

A semiconductor laser chip 60a according to the third embodiment has defect concentration regions 30 with a large number of defects on both sides (sides along arrows A and B) of an n-type GaN substrate 61 as shown in FIG. 15. The semiconductor laser chip 60a is so formed as to have a length (width) along arrow A (along arrow B) of about 400 μm. The n-type GaN substrate 61 is an example of the “substrate” in the present invention.

The semiconductor laser chip 60a is formed with a nitride-based semiconductor layer 62 including a ridge portion 62a constituting a light waveguide extending in a direction C in a striped (slender) manner on the n-type GaN substrates 61 similarly to the aforementioned first embodiment. The semiconductor layer 62 is an example of the “nitride-based semiconductor layer” in the present invention. A current blocking layer 64 of SiO₂ having a thickness of about 300 nm and a p-side pad electrode 65 are so formed on the semiconductor layer 62 as to cover a p-side electrodes 63. An n-side electrode 66 is formed on a back surface of the n-type GaN substrate 61. The p-side pad electrode 65 and the n-side electrode 66 are examples of the “second electrode layer” and the “first electrode layer” in the present invention respectively. Two cleavage planes 67 and 68 constituting cavity planes are formed perpendicular to the ridge portion 62a constituting the light waveguide. The cleavage planes 67 and 68 are examples of the “divided surfaces by a first division” in the present invention.

According to the third embodiment, in the semiconductor laser chip 60a, cleavage introducing step portions 69a and 69b are formed on a first side (side along arrow A) and cleavage introducing step portions 69c and 69d are formed on a second side (side along arrow B) as shown in FIG. 15, dissimilarly to the aforementioned first embodiment. The ridge portion 62a is formed on a region slightly close to a side along arrow A from a center 110 along arrow A (along arrow B) of the semiconductor laser chip 60a (n-type GaN substrate 61). The cleavage introducing step portions 69a, 69b, 69c and 69d are examples of the “second step portions” in the present invention.

The remaining structure of the GaN-based semiconductor laser chip (semiconductor laser chip 60a) according to the third embodiment is similar to that of the aforementioned first embodiment.

According to the third embodiment, an n-side electrode 66 side of the semiconductor laser chip 60a (n-type GaN substrate 61) is fixed on a radiator base (submount) 22 of AlN through solder 21 of Au—Sn in a junction-up system, as shown in FIG. 16. At this time, the fused solder 21 flows not only on a back surface side of the n-side electrode 66 of the semiconductor laser chip 60a but also flows into so as to conform shapes of the division introducing step portions 10a and 10b for being firmly fixed on the radiator base 22. Thus, the semiconductor laser chip 60a is reliably fixed on the radiator base 22.

A process of fabricating the GaN-based semiconductor laser chips according to the third embodiment in a wafer state (wafer process) will be now described with reference to FIGS. 15 to 17.

As shown in FIG. 15, the layers up to a p-side contact layer (not shown) are formed on the n-type GaN substrate 61 through a process similar to that of the aforementioned first embodiment. Thereafter the ridge portions (light waveguides) 62a and the p-side electrodes 63 are formed by vacuum evaporation and etching.

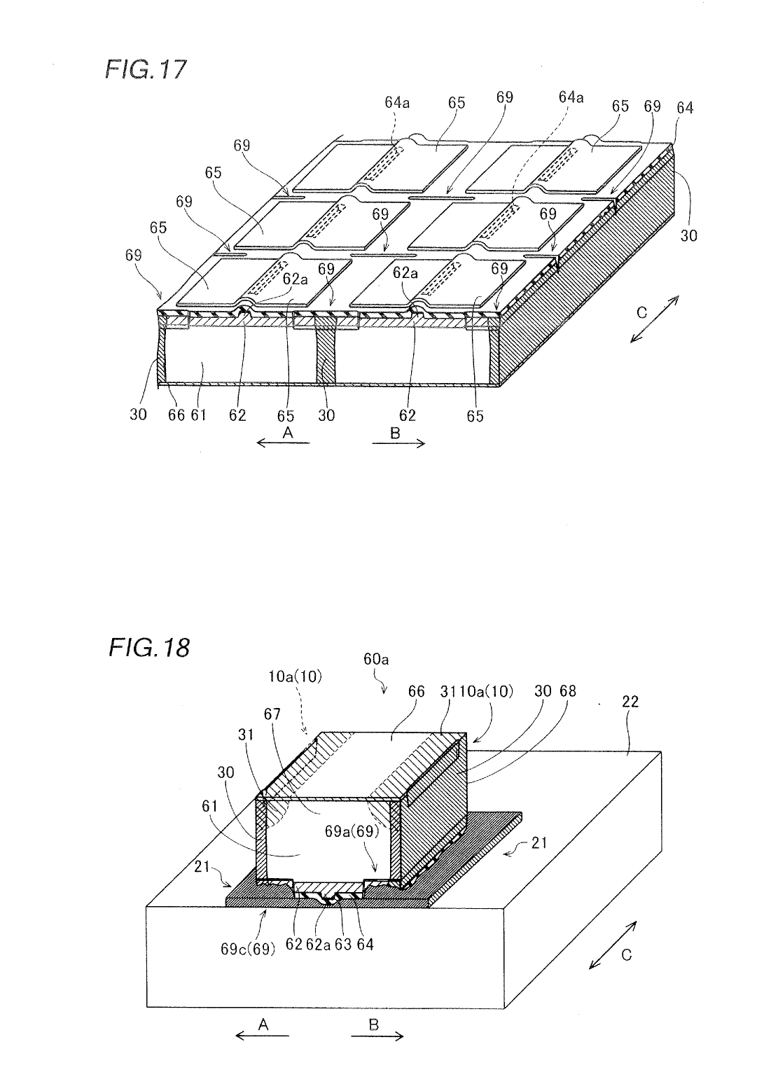

At this time, according to the third embodiment, the one ridge portion 62a is formed between the defect concentration regions 30 adjacent to each other as shown in FIG. 17.

The remaining fabrication process in the wafer state (wafer process) according to the third embodiment is similar to the fabricating process in the wafer state according to the aforementioned first embodiment.

A process of fabricating the GaN-based semiconductor laser chips according to the third embodiment subsequent to the wafer process (process of fabricating chips) will be now described with reference to FIGS. 15 to 17.

First, as shown in FIG. 17, the cleavage grooves 69 are formed on the regions including the defect concentration regions 30 and not including the ridge portions (light waveguides) 62a in a broken line fashion extending along arrow A (along arrow B) at every defect concentration region 30 through a process similar to that of the aforementioned first embodiment. In this state, the wafer is cleaved at a position of the cleavage grooves 69 along arrow A (along arrow B) (first division) through a process similar to that of the aforementioned first embodiment. Thus, the wafer is formed in the form of a bar where the GaN based-semiconductor laser chips are arranged in a row along arrow A (along arrow B).

Element dividing grooves 10 (see FIG. 15) are formed in a direction in which the striped ridge portions 62a extend (direction C) from the back surface side of the n-type GaN substrate 61 of the wafer cleaved in the form of a bar through a process similar to that of the aforementioned first embodiment.

At this time, according to the third embodiment, the element dividing grooves 10 are formed on regions spaced at prescribed distances W2 (about 20 μm) in the direction C from the cleavage planes 67 and 68 extending along arrow A (along arrow B) as shown in FIG. 15, similarly to the aforementioned first embodiment.

According to the third embodiment, the element dividing grooves 10 are formed on portions of the defect concentration regions 30 (see FIG. 15). In this state, the wafer in the form of a bar is divided at a position of the element dividing groove 10 along the direction C (second division), thereby fabricating a large number of the GaN-based semiconductor laser chips (semiconductor laser chips 60a) shown in FIG. 15 through a process similar to that of the aforementioned first embodiment.

The remaining fabricating process subsequent to the wafer process (method of fabricating chips) of the third embodiment is similar to the fabricating process subsequent to the wafer process of the aforementioned first embodiment.

According to the third embodiment, the aforementioned chipped semiconductor laser chip 60a placed with the n-side electrode 66 down is fusion bonded to the radiator base (submount) 22 through the solder 21 heated at a high temperature, as shown in FIG. 16. At this time, the fused solder 21 flows not only on the back surface side of the n-side electrode 66 of the semiconductor laser chip 60a but also flows into so as to conform shapes of the division introducing step portions 10a and 10b for being firmly fixed on the radiator base 22. Thus, the GaN-based semiconductor laser chip in the junction-up system is formed, similarly to the first embodiment.

According to the third embodiment, as hereinabove described, the division introducing step portions 10a and 10b are formed on positions corresponding to the defect concentration regions 30 on both side surfaces along arrow A (along arrow B) of the laser device along the direction in which the ridge portion 62a of the semiconductor laser chip 60a extends, whereby the ridge portion (light waveguide) 62a arranged on the center side of the laser device can be formed on the region separating from the defect concentration regions 30 on the both sides Thus, defects of the ridge portion 62a can be inhibited from increase.

According to the third embodiment, the n-side electrode 66 side opposite to the side on which the semiconductor layer 62 of the n-type GaN substrate 61 is formed is mounted on the radiator base 22 through the solder 21 of Au—Sn similarly to the aforementioned first embodiment, whereby the solder 21 is not only firmly fixed on the back surface of the n-side electrode 66 but also intrudes in the recessed division introducing step portions 10a and 10b from the back surface for firmly fixing and hence the semiconductor laser chip 60a can be stably fixed on the radiator base 22. Consequently, axial deviation of laser emission light can be inhibited. The remaining effects of the third embodiment are similar to those of the aforementioned first embodiment.

### Modification of Third Embodiment

In a GaN-based semiconductor laser chip according to a modification of a third embodiment, a semiconductor laser chip 60a is fixed on a radiator base 22 in a junction-down system, dissimilarly to the aforementioned third embodiment.

According to the modification of the third embodiment, an p-side pad electrode 65 side of the semiconductor laser chip 60a (n-type GaN substrate 61) is fixed on the radiator base (submount) 22 of AlN through solder 21 of Au—Sn in the junction-down system, as shown in FIG. 18. In this case, the fused solder 21 flows not only on a surface side of the p-side pad electrode 65 of the semiconductor laser chip 60a but also flows into so as to conform shapes of four cleavage introducing step portions 69a, 69b, 69c and 69d formed on semiconductor layer 62 sides of cleavage planes 67 and 68 for being firmly fixed on the radiator base 22, and hence the semiconductor laser chip 60a is reliably fixed on the radiator base 22.

According to the modification of the third embodiment, as hereinabove described, the p-side pad electrode 65 side formed with the semiconductor layer 62 of the n-type GaN substrate 61 is mounted on the radiator base 22 through the solder 21 of Au—Sn, whereby the solder 21 is not only firmly fixed on the surface of the p-side pad electrode 65 but also intrudes in the recessed cleavage introducing step portions 69a, 69b, 69c and 69d (four portions) from the surface for firmly fixing and hence the semiconductor laser chip 60a can be stably fixed on the radiator base 22. Consequently, axial deviation of laser emission light can be inhibited. The fused solder 21 intrudes in the cleavage introducing step portions 69a and 69c (see FIG. 18) for firmly fixing and hence does not stick out in the vicinity of the ridge portion (light waveguide) 62a of a cavity facet (cleavage plane 67). Thus, the solder 21 can be inhibited from hindering laser emission light from the emission point under the ridge portion 62a. The remaining effects of the modification of the third embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the present invention is applied to the GaN-based semiconductor laser chip in each of the aforementioned embodiments, the present invention is not restricted to this but also applicable to a nitride-based semiconductor device other than the GaN-based semiconductor laser device.

While the element dividing grooves are formed on the regions spaced at distances of about 20 μm from the cleavage planes in each of the aforementioned embodiments, the present invention is not restricted to this but the element dividing grooves may be alternatively formed on regions spaced at distances other than about 20 μm from the cleavage planes For example, in a case where the element dividing grooves are formed on regions spaced at distances larger than about 20 μm from the cleavage planes, the debris can be further inhibited from adhering to the ridge portions (light waveguides) when forming the element dividing grooves and hence the thickness of a wafer (n-type GaN substrate) can further reduced.

While the n-type GaN substrate formed with the region having a large number of defects in a linear fashion is employed in each of the aforementioned embodiments, the present invention is not restricted to this but an n-type GaN substrate formed with a region having a large number of defects in a meshed fashion other than the linear fashion may be alternatively employed, for example.

While the wafer is cleaved or divided with the edged tool in each of the aforementioned embodiments, the present invention is not restricted to this but the wafer is cleaved or divided with a roller other than the edged tool, for example.

While SiO₂ and TiO₂ are employed as the facet coat material in each of the aforementioned embodiments, the present invention is not restricted to this but Al₂O₃, ZrO₂, Ta₂O₅ Nb₂O₅, La₂O₃, SiN, AlN or BN or the like other than SiO₂ and TiO₂ or Ti₃O₅ or Nb₂O₃ as a material having different composition ratios of these may be alternatively employed as the facet coat material, for example.

While the wafer (n-type GaN substrate) is so formed as to have a thickness of about 130 μm in each of the aforementioned embodiments, the present invention is not restricted to this but the wafer (n-type GaN substrate) may be alternatively formed to have a thickness other than about 130 μm.

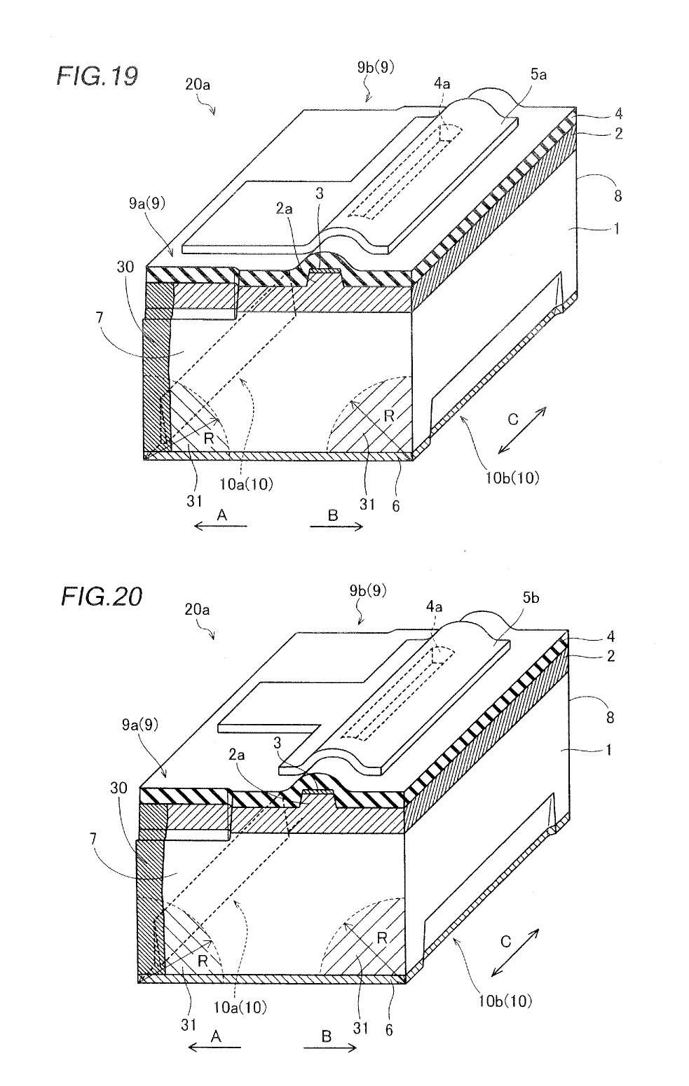

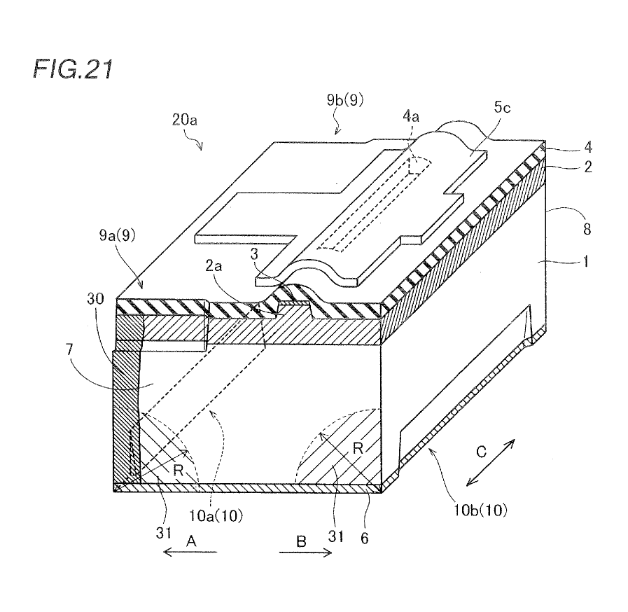

While the p-side pad electrode is formed on the regions inside from the positions forming the facets (four sides) of the semiconductor laser chip by equal distances in each of the aforementioned embodiments, the present invention is not restricted to this but the distances may not be equal or other shape may be employed. For example, the p-side pad electrode may be formed in a circular or polygonal shape or a shape according to each of second to fourth modifications of the first embodiment of the present invention shown in FIGS. 19 to 21. In this case, the areas of p-side pad electrodes 5a to 5c can be reduced in the second to fourth modifications, and hence the capacitance of the semiconductor laser chips can be reduced. Thus response characteristics (high-frequency characteristics) of the semiconductor laser chips can be improved. Additionally, directions of the semiconductor laser chips can be easily identified only by viewing the semiconductor laser chips (p-side pad electrodes 5a to 5c) from the above in the second to fourth modifications (particularly, second modification), and hence emission direction of laser beam can be easily identified.

While the one, two or three GaN-based semiconductor laser chip(s) is(are) formed between the defect concentration regions adjacent to each other in each of the aforementioned embodiments, the present invention is not restricted to this but four or more GaN-based semiconductor laser chips may be alternatively formed between the defect concentration regions adjacent to each other.

While the three GaN-based semiconductor laser chips having widths of about 150 μm, about 100 μm and about 150 μm respectively are formed between the defect concentration regions adjacent to each other in the second embodiment, the present invention is not restricted to this but three GaN-based semiconductor laser chips having the same widths may be alternatively formed between the defect concentration regions adjacent to each other.

According to the second embodiment, the three GaN-based semiconductor laser chips are formed between the defect concentration regions adjacent to each other and the ridge portion (light waveguide) of the central laser chip is so formed as to be located at the center of the laser chip in the second embodiment, the present invention is not restricted to this but the ridge portion (light waveguide) of the central laser chip may be alternatively formed at a position close to a first side.

While the depths of the element dividing grooves formed on the back surface side of the substrate and the depths of the cleavage grooves formed on the semiconductor layer side of the substrate both are about 40 μm in each of the aforementioned embodiments, the present invention is not restricted to this but the depths of the element dividing grooves and the cleavage grooves may be alternatively formed in the range of at least 3 μm and not more than 100 μm.

While the radiator base of AlN is employed as the submount for fixing the semiconductor laser chip in each of the aforementioned embodiments, the present invention is not restricted to this but a radiator base consisting of other material such as SiC, Si, BN, diamond, Cu, CuW and Al may be alternatively employed. While the solder of Au—Sn is employed as the fusion layer for fixing the laser chip on the radiator base, the present invention is not restricted to this but a fusion layer consisting of other material such as Ag—Sn, Pb—Sn and In—Sn may be alternatively employed.

What is claimed is:

1. A method of fabricating a nitride-based semiconductor device, comprising steps of:
forming a nitride-based semiconductor layer having light waveguides extending in a first direction on a substrate;
performing a first division along a second direction intersecting with said first direction in which said light waveguides extend;
forming element dividing grooves extending in said first direction on regions spaced at prescribed distances from divided surfaces by said first division extending in said second direction on a surface opposite to a side on which said nitride-based semiconductor layer of said substrate is formed by irradiation of laser beam; and
forming nitride-based semiconductor devices by performing a second division along said element dividing grooves.

2. The method of fabricating a nitride-based semiconductor device according to claim 1, wherein
said substrate has a plurality of defect concentration regions extending in said first direction and provided at prescribed intervals in said second direction.

3. The method of fabricating a nitride-based semiconductor device according to claim 2, wherein
said step of forming said nitride-based semiconductor layer having said light waveguides extending in said first direction on said substrate includes a step of forming at least two said light waveguides between adjacent said defect concentration regions extending in said first direction, and
said step of forming said element dividing grooves on said substrate includes a step of forming said element dividing grooves on said defect concentration regions and centers between said light waveguides.

4. The method of fabricating a nitride-based semiconductor device according to claim 3, wherein
distances from said centers between adjacent said light waveguides to said light waveguides are at most distances from said defect concentration regions to said light waveguides.

5. The method of fabricating a nitride-based semiconductor device according to claim 2, wherein
said step of forming said nitride-based semiconductor layer having said light waveguides extending in said first direction on said substrate includes a step of forming at least one said light waveguide between adjacent said defect concentration regions extending in said first direction; and
said step of forming said element dividing grooves on said substrate includes a step of forming said element dividing grooves so as to correspond to said defect concentration regions provided on both sides of said light waveguides.

6. The method of fabricating a nitride-based semiconductor device according to claim 1, wherein
said step of forming said element dividing grooves on said substrate further includes a step of forming said element dividing grooves so as to have lengths of at least ⅕ of distances between facets of said light waveguides in said first direction.

7. The method of fabricating a nitride-based semiconductor device according to claim 1, further comprising a step of forming a first electrode layer on said surface opposite to said side on which said nitride-based semiconductor layer of said substrate is formed, wherein
said step of forming said element dividing grooves includes a step of forming said element dividing grooves up to depths reaching inside said substrate from a side of said first electrode layer.

8. The method of fabricating a nitride-based semiconductor device according to claim 2, wherein
said step of performing said first division includes:
a step of forming cleavage grooves provided in a broken line fashion at every said defect concentration region so as to extend in said second direction on at least regions including said defect concentration regions of said nitride-based semiconductor layer and not including said light waveguides by irradiation of laser beam, and
a step of forming cavity facets by performing cleavage along said cleavage grooves.

9. The method of fabricating a nitride-based semiconductor device according to claim 8, wherein
said step of forming said cleavage grooves provided in the broken line fashion so as to extend in said second direction includes a step of forming said cleavage grooves so as to have the lengths of at least 1/20 of the width of said nitride-based semiconductor device in said second direction.

10. The method of fabricating a nitride-based semiconductor device according to claim 8, wherein
said step of forming said cleavage grooves includes a step of forming said cleavage grooves up to depths reaching inside said substrate from a side of said nitride-based semiconductor layer.

11. The method of fabricating a nitride-based semiconductor device according to claim 8, further comprising a step of forming second electrode layers on said nitride-based semiconductor layer, wherein
said step of forming said cleavage grooves includes a step of forming said cleavage grooves on said defect concentration regions where said second electrode layers are not formed.

12. The method of fabricating a nitride-based semiconductor device according to claim 1, further comprising a step of mounting either a side of said nitride-based semiconductor layer or a side of said substrate on a radiator base through a fusion layer after said step of performing said first division and said step of forming said nitride-based semiconductor devices by performing said second division.

13. A nitride-based semiconductor device comprising:
a substrate constituted by nitride-based semiconductor;
a nitride-based semiconductor layer formed on said substrate and constituted by nitride-based semiconductor, formed with a light waveguide extending in a first direction; and
first step portions formed at least on regions other than the vicinity of facets including said light waveguide from a surface opposite to a side where said nitride-based semiconductor layer of said substrate is formed along said first direction in which said light waveguide extends.

14. The nitride-based semiconductor device according to claim 13, wherein
the length of each of said first step portions in said first direction is at least ⅕ of a distance between said facets of said light waveguide in said first direction.

15. The nitride-based semiconductor device according to claim 13, further comprising a first electrode layer formed on said surface opposite to said side where said nitride-based semiconductor layer of said substrate is formed, wherein
each of said first step portions is so formed as to have a depth reaching inside said substrate from a side of said first electrode layer.

16. The nitride-based semiconductor device according to claim 13, wherein
said substrate has a plurality of defect concentration regions extending in said first direction in which said light waveguide extends and provided at a prescribed interval in a second direction intersecting with said first direction, and
second step portions are formed at least on regions including said defect concentration regions of said nitride-based semiconductor layer and not including said facets in the vicinity of said light waveguide at prescribed distances from said light waveguide so as to extend in said second direction at every said defect concentration region.

17. The nitride-based semiconductor device according to claim 16, further comprising a second electrode layer formed on said nitride-based semiconductor layer, wherein
said second electrode layer is formed at a prescribed interval from each of said second step portions.

18. The nitride-based semiconductor device according to claim 16, wherein
the length of each of said second step portions in said second direction is at least 1/20 of the width of said nitride-based semiconductor device in said second direction.

19. The nitride-based semiconductor device according to claim 18, wherein
each of said second step portions is so formed as to have a depth reaching inside said substrate from a side of said nitride-based semiconductor layer.

20. The nitride-based semiconductor device according to claim 13, wherein
either a side of said nitride-based semiconductor layer or a side of said substrate is mounted on a radiator base through a fusion layer.
